(19) United States
(12) Patent Application Publication
(10) Pub. No.: US 2025/0063853 A1
(43) Pub. Date: Feb. 20, 2025

(54) SINGLE-PHOTON AVALANCHE DIODES WITH AN INTEGRATED ACTIVE DEVICE

(71) Applicant: GlobalFoundries Singapore Pte. Ltd., Singapore (SG)

(72) Inventors: Francesco Gramuglia, Augsburg (DE); Eng-Huat Toh, Singapore (SG); Kiok Boone Elgin Quek, Singapore (SG)

(21) Appl. No.: 18/234,469

(22) Filed: Aug. 16, 2023

(51) Int. Cl. H01L 31/02; H01L 21/763; H01L 31/107

(52) U.S. Cl. CPC H01L 31/02027; H01L 21/763; H01L 31/107

(57) ABSTRACT

Structures including a single-photon avalanche diode and methods of forming such structures. The structure comprises a semiconductor substrate including a trench. The trench surrounds a portion of the semiconductor substrate. The structure further comprises a deep trench isolation region that includes a dielectric layer and a semiconductor layer inside the trench. The dielectric layer is disposed between a sidewall of the trench and the semiconductor layer. The structure further comprises an active device that includes a doped region in the semiconductor layer.

### BACKGROUND

The disclosure relates to semiconductor device fabrication and integrated circuits and, more specifically, to structures including a single-photon avalanche diode and methods of forming such structures.

A single-photon avalanche diode (SPAD) is a type of solid-state photodetector belonging to the same family as photodiodes and avalanche photodiodes. A fundamental difference between single-photon avalanche diodes and other types of photodetectors is that a single-photon avalanche diode is biased well above its reverse-bias breakdown voltage. When a single-photon avalanche diode is placed under such a high reverse bias, photon-initiated charge carriers are accelerated by the electric field to a kinetic energy that is large enough to knock electrons out of atoms of the bulk material and generate additional charge carriers that may exponentially grow to generate an avalanche of charge carriers. A single-photon avalanche diode can detect single photons providing short duration current pulses that can be counted or used to obtain a time of arrival of a particular incident single photon.

An electrical circuit including a single-photon avalanche diode tends to have a large footprint. A transistor is used to control the operation of the single-photon avalanche diode. The transistor tends to be large and consumes significant chip area. A single-photon avalanche diode may be electrically isolated from its surroundings by a deep trench isolation region. Deep trench isolation regions may also consume significant chip area.

Improved structures including a single-photon avalanche diode and methods of forming such structures are needed.

### SUMMARY

In an embodiment of the invention, a structure comprises a semiconductor substrate including a trench. The trench surrounds a portion of the semiconductor substrate. The structure further comprises a deep trench isolation region that includes a dielectric layer and a semiconductor layer inside the trench. The dielectric layer is disposed between a sidewall of the trench and the semiconductor layer. The structure further comprises an active device that includes a doped region in the semiconductor layer.

In an embodiment of the invention, a method comprises forming a trench in a semiconductor substrate and forming a deep trench isolation region that includes a dielectric layer and a semiconductor layer inside the trench. The trench surrounds a portion of the semiconductor substrate, and the dielectric layer is disposed between a sidewall of the trench and the semiconductor layer. The method further comprises forming an active device including a doped region in the semiconductor layer.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention. In the drawings, like reference numerals refer to like features in the various views.

FIG. 1 is a top view of a structure at an initial fabrication stage of a processing method in accordance with embodiments of the invention.

FIG. 2 is a cross-sectional view taken generally along line 2-2 in FIG. 1.

FIG. 3 is a cross-sectional view of the structure at a fabrication stage subsequent to FIGS. 1, 2.

FIG. 4 is a cross-sectional view of the structure at a fabrication stage subsequent to FIG. 3.

FIG. 5 is a cross-sectional view of the structure at a fabrication stage subsequent to FIG. 4.

FIG. 6 is a cross-sectional view of the structure at a fabrication stage subsequent to FIG. 5.

FIG. 7 is a cross-sectional view of the structure at a fabrication stage subsequent to FIG. 6.

FIG. 8 is a cross-sectional view of a structure in accordance with alternative embodiments of the invention.

### DETAILED DESCRIPTION

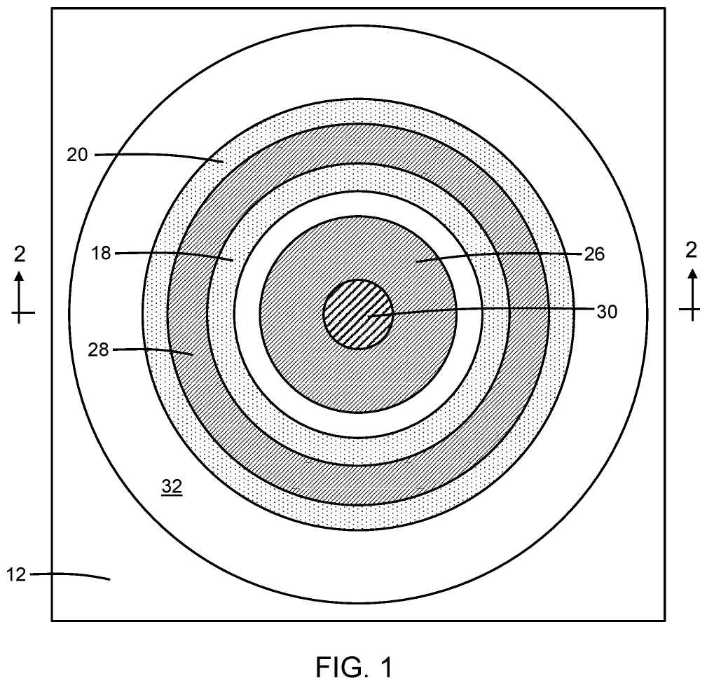

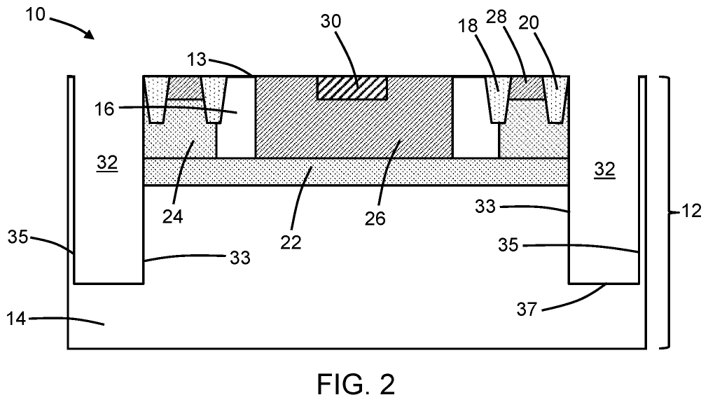

With reference to FIGS. 1, 2 and in accordance with embodiments of the invention, a structure 10 including a single-photon avalanche detector may be formed using a semiconductor substrate 12 that includes a bulk substrate 14 and a semiconductor layer 16 disposed on the bulk substrate 14. In an embodiment, the bulk substrate 14 may be comprised of a single-crystal semiconductor material, such as silicon, that is lightly-doped with a p-type dopant (e.g., boron) to provide p-type conductivity. In an embodiment, the semiconductor layer 16 may be comprised of a semiconductor material, such as single-crystal silicon, that is epitaxially grown as a blanket film using an epitaxial growth process. In an embodiment, the semiconductor layer 16 may be comprised of single-crystal silicon that is intrinsic.

Shallow trench isolation regions 18, 20 may be disposed in portions of the semiconductor substrate 12. In an embodiment, the shallow trench isolation regions 18, 20 may be formed by applying and patterning a hardmask, etching trenches using the patterned hardmask, depositing a dielectric material (e.g., silicon dioxide) in the trenches, and planarizing with chemical-mechanical polishing.

A deep well 22 is disposed in a portion of the semiconductor substrate 12 and is spaced in a vertical direction from the top surface 13 of the semiconductor substrate 12. In an embodiment, the deep well 22 may be formed by introducing a dopant by, for example, a masked ion implantation into the semiconductor substrate 12. A patterned implantation mask may be formed to define a selected area (e.g., location and horizontal dimensions) on a top surface 13 of the semiconductor substrate 12 that is exposed for implantation to form the deep well 22. The implantation conditions (e.g., ion species, dose, kinetic energy) may be selected to tune the electrical and physical characteristics of the deep well 22. In an embodiment, the deep well 22 may be doped with a concentration of an n-type dopant (e.g., arsenic or phosphorus) such that the deep well 22 has n-type conductivity.

A well 24 is disposed in a portion of the semiconductor substrate 12 adjacent to the top surface 13 of the semiconductor substrate 12. In an embodiment, the well 24 may be formed in a peripheral portion of the semiconductor layer 16 and may surround a central portion of the semiconductor layer 16. A patterned implantation mask may be formed to define a selected area (e.g., location and horizontal dimensions) on the top surface 13 of the semiconductor substrate 12 that is exposed for implantation to form the well 24. The implantation conditions (e.g., ion species, dose, kinetic energy) may be selected to tune the electrical and physical characteristics of the well 24. In an embodiment, the well 24 may be formed by introducing a dopant by, for example, a masked ion implantation into the semiconductor substrate 12. In an embodiment, the well 24 may be doped with a concentration of an n-type dopant (e.g., arsenic or phosphorus) such that the well 24 has n-type conductivity. In an embodiment, the well 24 may be doped to have the same conductivity type as the deep well 22. The well 24 may contain a higher dopant concentration of the n-type dopant than the deep well 22.

A well 26 may be disposed in a central portion of the semiconductor layer 16 adjacent to the top surface 13 of the semiconductor substrate 12. In an embodiment, the well 26 may be formed by introducing a dopant by, for example, a masked ion implantation into the semiconductor substrate 12. A patterned implantation mask may be formed to define a selected area (e.g., location and horizontal dimensions) on the top surface 13 of the semiconductor substrate 12 that is exposed for implantation to form the well 26. The implantation conditions (e.g., ion species, dose, kinetic energy) may be selected to tune the electrical and physical characteristics of the well 26. In an embodiment, the well 26 may be doped with a concentration of a p-type dopant (e.g., boron) such that the well 26 has p-type conductivity.

The well 24 may adjoin a portion of the deep well 22. The deep well 22 and the well 24 may be doped to have the same conductivity type. The well 26 may also adjoin a portion of the deep well 22. The well 26 and the deep well 22 may be doped to have opposite conductivity types. The well 24 may surround the well 26, and an undoped portion of the semiconductor layer 16 may be disposed between the well 26 and the well 24. The well 24 and the well 26 are positioned in a vertical direction between the deep well 22 and the top surface 13 of the semiconductor substrate 12.

A doped region 28 may be disposed in a portion of the well 24 adjacent to the top surface 13 of the semiconductor substrate 12. In an embodiment, the doped region 28 may be formed by introducing a dopant by, for example, a masked ion implantation into the semiconductor substrate 12. A patterned implantation mask may be formed to define a selected area (e.g., location and horizontal dimensions) on the top surface 13 of the semiconductor substrate 12 that is exposed for implantation to form the doped region 28. The implantation conditions (e.g., ion species, dose, kinetic energy) may be selected to tune the electrical and physical characteristics of the doped region 28. In an embodiment, the doped region 28 may be doped with a concentration of an n-type dopant (e.g., arsenic or phosphorus) such that the doped region 28 has n-type conductivity. In an embodiment, the doped region 28 may be doped to have the same conductivity type as the well 24. The doped region 28 may contain a higher dopant concentration of the n-type dopant than the well 24.

A doped region 30 may be disposed in a central portion of the well 26 adjacent to the top surface 13 of the semiconductor substrate 12. In an embodiment, the doped region 30 may be formed by introducing a dopant by, for example, a masked ion implantation into the semiconductor substrate 12. A patterned implantation mask may be formed to define a selected area (e.g., location and horizontal dimensions) on the top surface 13 of the semiconductor substrate 12 that is exposed for implantation to form the doped region 30. The implantation conditions (e.g., ion species, dose, kinetic energy) may be selected to tune the electrical and physical characteristics of the doped region 30. In an embodiment, the doped region 30 may be doped with a concentration of a p-type dopant (e.g., boron) such that the doped region 30 has p-type conductivity. In an embodiment, the doped region 30 may be doped to have the same conductivity type as the well 24. The doped region 30 may contain a higher dopant concentration of the n-type dopant than the well 24.

The doped region 28 and the doped region 30 may define terminals of the single-photon avalanche detector. In an embodiment, the doped region 28 may define a cathode of the single-photon avalanche detector, and the doped region 30 may define an anode of the single-photon avalanche detector. An absorption/multiplication region of the single-photon avalanche diode is defined by the wells 24, 26 and deep well 22.

A trench 32 is formed in the semiconductor substrate 12 as an opening that penetrates fully through the semiconductor layer 16 and into the bulk substrate 14. The trench 32 extends through the well 24 and the deep well 22. The trench 32 may surround a portion of the semiconductor substrate 12 and, in particular, may surround respective portions of the bulk substrate 14 and the semiconductor layer 16. The trench 32 may be patterned by lithography and etching processes. To that end, an etch mask may be formed by a lithography process over the semiconductor substrate 12. The etch mask may include a layer of a light-sensitive material, such as a photoresist, applied by a spin-coating process, pre-baked, exposed to light projected through a photomask, baked after exposure, and developed with a chemical developer to define an opening at the location of the subsequently-etched trench 32. An etching process is used to form the trench 32 at the location of the opening in the etch mask. In an embodiment, the trench 32 may have a width of about 0.8 microns to about 1 micron and a depth in a range of about 7 microns to about 10 microns. The etch mask may be stripped by, for example, ashing after forming the trench 32.

The trench 32 includes an inner sidewall 33 that surrounds a portion of the semiconductor substrate 12 and an outer sidewall 35 that surrounds the inner sidewall 33. The terminals of the single-photon avalanche diode are formed in the portion of the semiconductor substrate 12 that is surrounded by the inner sidewall 33. The trench 32 has a closed shape. In the representative embodiment, the trench 32 is annular with circular sidewalls 33, 35. In an alternative embodiment, the trench 32 may have a different shape, such as a shape with polygonal sidewalls 33, 35.

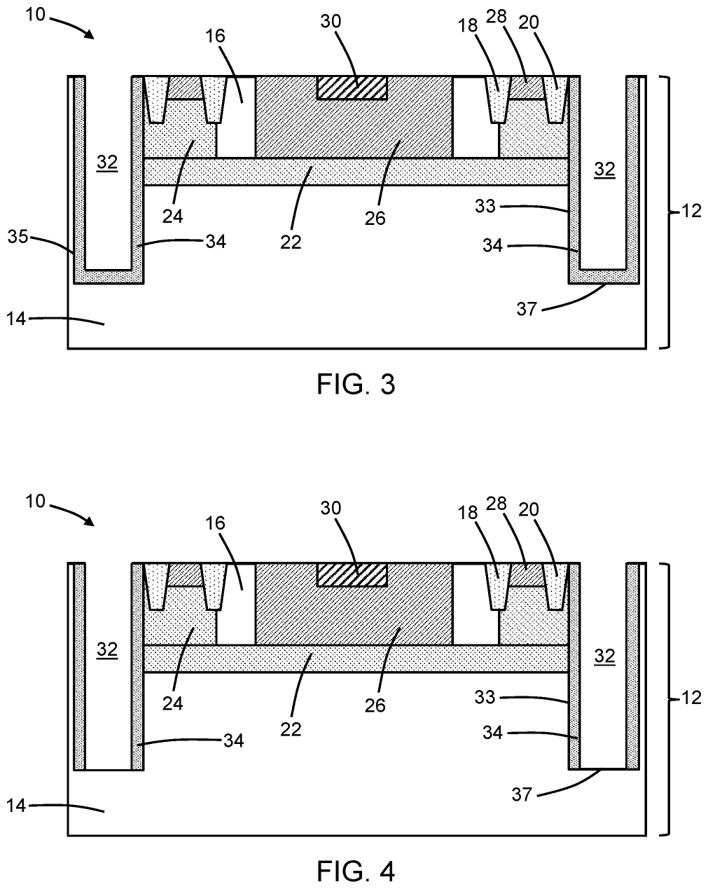

With reference to FIG. 3 in which like reference numerals refer to like features in FIGS. 1, 2 and at a subsequent fabrication stage of the processing method, a dielectric layer 34 is formed on the sidewalls 33, 35 and bottom 37 of the trench 32. The dielectric layer 34 may be comprised of, for example, silicon dioxide, and the dielectric layer 34 may have a conformal thickness. In an embodiment, the dielectric layer 34 may have a conformal thickness in a range of about 0.2 microns to about 0.3 microns such that the trench 32 is only partially filled.

With reference to FIG. 4 in which like reference numerals refer to like features in FIG. 3 and at a subsequent fabrication stage of the processing method, the dielectric layer 34 may be selectively removed from the bottom 37 of the trench 32 by an etching process to expose a portion of the bulk substrate 14 is exposed at the bottom 37 of the trench 32. Portions of the dielectric layer 34 on the sidewalls 33, 35 of the trench 32 are preserved and intact following the etching process.

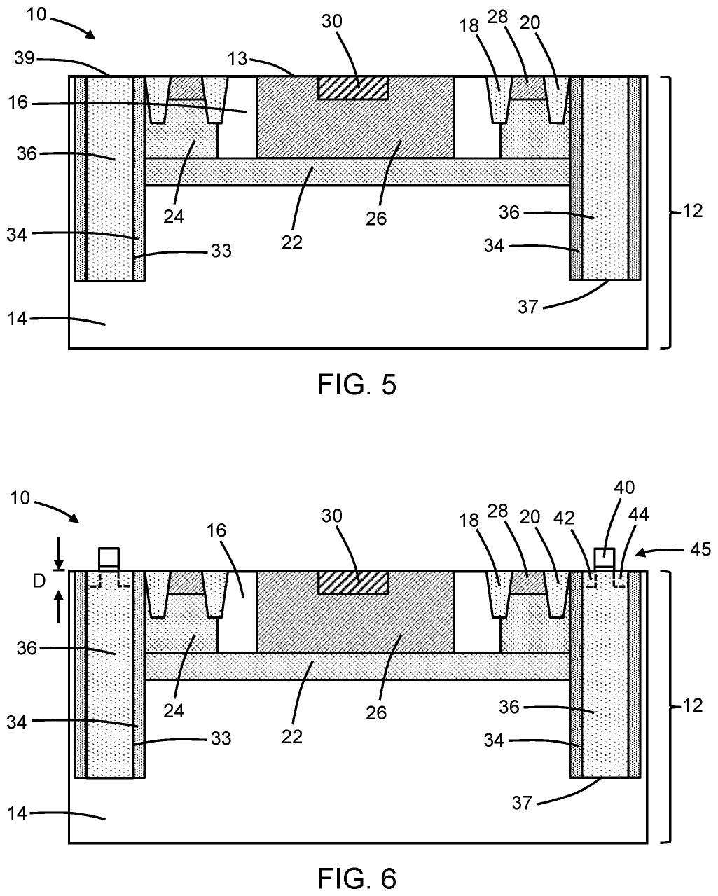

With reference to FIG. 5 in which like reference numerals refer to like features in FIG. 4 and at a subsequent fabrication stage of the processing method, a semiconductor layer 36 is formed inside the trench 32 as a core arranged interior of the dielectric layer 34. The semiconductor layer 36 may be comprised of a semiconductor material that is deposited and planarized by chemical-mechanical polishing. In an embodiment, the semiconductor layer 36 may be comprised of single-crystal silicon. In an embodiment, the semiconductor layer 36 may be comprised of amorphous silicon. In an embodiment, the semiconductor layer 36 may be comprised of polycrystalline silicon. The dielectric layer 34 is arranged in the trench 32 between the semiconductor substrate 12 at the inner sidewall 33 of the trench 32 and the semiconductor layer 36. The dielectric layer 34 is also arranged in the trench 32 between the semiconductor substrate 12 at the outer sidewall 35 of the trench 32 and the semiconductor layer 36. The semiconductor layer 36 may be in direct contact with the semiconductor substrate 12 at the bottom 37 of the trench 32. The semiconductor layer 36 has a top surface 39 that may be coplanar or substantially coplanar with the top surface 13 of the semiconductor substrate 12.

The dielectric layer 34 and semiconductor layer 36 that are positioned inside the trench 32 collectively define a deep trench isolation region 38. The dielectric layer 34 electrically isolates the semiconductor layer 36 from the portion of the semiconductor substrate 12 that is surrounded by the deep trench isolation region 38. In an embodiment, the deep trench isolation region 38 may be included in a grid of deep trench isolation regions 38 in which each grid square includes a single-photon avalanche diode.

With reference to FIG. 6 in which like reference numerals refer to like features in FIG. 5 and at a subsequent fabrication stage of the processing method, a transistor 45 may be formed as an active device in the semiconductor layer 36. In an embodiment, the transistor 45 may be a field-effect transistor that includes a gate 40 and source/drain regions 42, 44. The gate 40 may include a gate electrode and a gate dielectric layer formed by depositing a layer stack and patterning the layer stack with photolithography and etching processes. The gate electrode of the gate 40 may be comprised of a conductor, such as doped polycrystalline silicon (i.e., polysilicon) or a work function metal, and the gate dielectric layer of the gate 40 may be comprised of an electrical insulator, such as silicon dioxide or hafnium oxide.

The source/drain regions 42, 44 of the transistor 45 may be doped regions that are formed in the semiconductor layer 36 by, for example, a masked ion implantation. The source/drain regions 42, 44 may be doped with a concentration of a dopant, such as an n-type dopant (e.g., arsenic or phosphorus) that provides n-type conductivity. Alternatively, source/drain regions 42, 44 may be doped with a concentration of a p-type dopant (e.g., boron) that provides p-type conductivity. As used herein, the term “source/drain region” means a doped region of semiconductor material that can function as either a source or a drain of a field-effect transistor. In an embodiment, the source/drain region 42 may represent the drain of the transistor 45, and the source/drain region 44 may represent the source of the transistor 45. The doped regions representing the source/drain regions 42, 44 may be coextensive with the top surface 39 of the semiconductor layer 36. The doped regions representing the source/drain regions 42, 44 may extend from the top surface 39 of the semiconductor layer 36 to a depth D in the semiconductor layer 36 that is shallower than the depth of the doped regions 28, 30. The trench 32 extends to a depth in the semiconductor substrate 12 that is greater than the depth D.

In an embodiment, the gate 40 and source/drain regions 42, 44 of the transistor 45 in the semiconductor layer 36 of the deep trench isolation region 38 may fully surround the perimeter of the single-photon avalanche detector. In an alternative embodiment, the gate 40 and source/drain regions 42, 44 may be divided such that multiple transistors 45 are disposed in the semiconductor layer 36 of the deep trench isolation region 38 about the perimeter of the single-photon avalanche detector.

Other types of active devices may be formed in addition to the transistor 45 or instead of the transistor 45. As used herein, an active device is a circuit component with the ability to electrically control charge flow through the circuit component under either voltage control or current control. An active device is distinguishable over a passive device, such as a resistor. In an exemplary alternative embodiment, a silicon-controlled rectifier may be formed as an active device that includes multiple doped regions in the semiconductor layer 36.

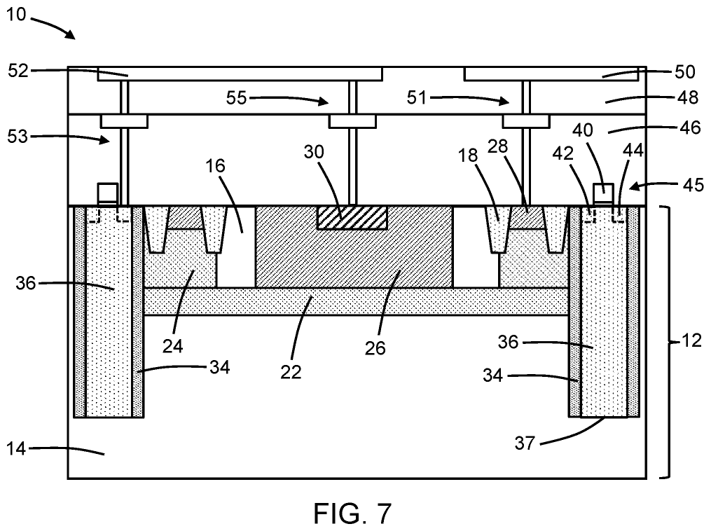

With reference to FIG. 7 in which like reference numerals refer to like features in FIG. 6 and at a subsequent fabrication stage of the processing method, dielectric layers 46, 48 may be formed over the semiconductor substrate 12. The dielectric layers 46, 48 may be comprised of dielectric material, such as silicon dioxide. Each of the dielectric layers 46, 48 may define a metallization level of an interconnect structure that may be used to electrically couple the transistor 45 to the single-photon avalanche detector.

A wire 50 is formed defining a metal feature in the dielectric layer 48, and the wire 50 may be physically and electrically connected by metal features 51 of the metallization levels to the doped region 28 of the single-photon avalanche detector. A wire 52 is formed defining a metal feature in the dielectric layer 48, and the wire 52 may be physically and electrically connected by metal features 53 in the metallization levels to the source/drain region 42 of the transistor 45. The wire 52 is also physically and electrically connected by metal features 55 in the metallization levels to the doped region 30 of the single-photon avalanche detector such that the wire 52 is configured to connect the source/drain region 42 of the transistor 46 to the doped region 30 of the single-photon avalanche diode. The metal features 51, 53, 55 may include vias, contacts, and wires that are formed in the dielectric layers 46, 48. The source/drain region 44 of the transistor 45 and the gate 40 of the transistor 45 may also be connected to metal features (not shown) in the metallization levels. For the example, the source/drain region 44 of the transistor 45 may be coupled by the metal features to ground, and the gate 40 of the transistor 45 may be coupled to a control voltage.

The structure 10 may be replicated to provide multiple instances of the single-photon avalanche diode and transistor 45, and these instances of the single-photon avalanche diode and transistor 45 may be arranged as pixels in a pixel array to define, for example, an image sensor. The image sensor may be used in mobile phones, digital cameras, and other types of devices.

In use, the p-n junction between the deep well 22 and the well 26 may be reverse-biased above the breakdown voltage. The single-photon avalanche diode is illuminated by light, and incident photons are absorbed in the portions of the semiconductor layer 16 interior of the deep trench isolation region 38. When an incident photon is absorbed, an electron-hole pair is created. An avalanche current is generated under the reverse bias by the creation of additional electron-hole pairs through impact ionization with atoms of the semiconductor material. The current continues to be generated until the avalanche is quenched by lowering the bias to less than or equal to the breakdown voltage. The collected current provides a detectable electronic signal. To be able to detect another photon, the reverse bias is raised again above breakdown voltage to recharge the single-photon avalanche diode.

The structure 10 utilizes the semiconductor layer 36 of the deep trench isolation region 38 to provide functionality through the integration of an active device. The structure 10 may be more compact and have a smaller form factor than traditional structures because the representative active device, namely the transistor 45, is integrated into the semiconductor layer 36 of the deep trench isolation region 38. The dielectric layer 34 of the deep trench isolation region 38 supplies electrical isolation for the surrounded single-photon avalanche diode relative to adjacent single-photon avalanche diodes. The transistor 45 may be used to control the operation of the single-photon avalanche diode. For example, the transistor 45 may be used to control the quenching of the single-photon avalanche diode and to control the recharging of the single-photon avalanche diode.

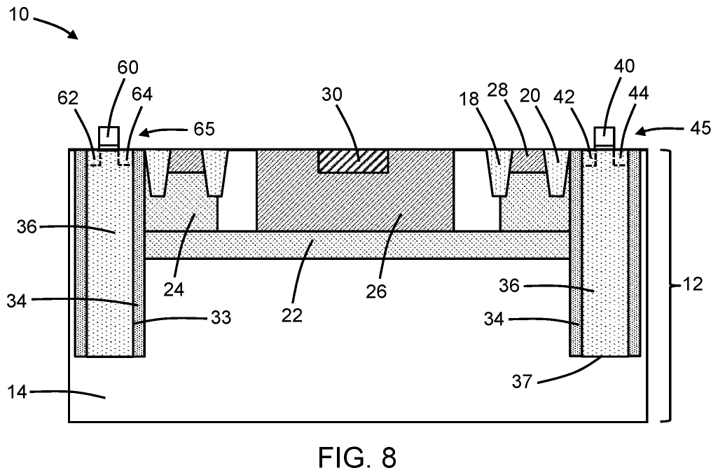

With reference to FIG. 8 and in accordance with alternative embodiments, the structure 10 may be modified to integrate multiple active devices. In an embodiment, the structure 10 may include another transistor 65 having a gate 60 like the gate 40 of the transistor 45 and source-drain regions 62, 64 like the source/drain regions 42, 44 of the transistor 45. The gate 60 is disposed on the top surface 39 of the semiconductor layer 36, and the source/drain regions 42, 44 are doped regions disposed in the semiconductor layer 36. The source/drain regions 62, 64 of the transistor 65 may be electrically isolated from the source/drain regions 42, 44 of the transistor 45 by, for example, shallow trench isolation regions formed in the semiconductor layer 36. In alternative embodiments, more than two active devices may be integrated into the semiconductor layer 36 of the deep trench isolation region 38.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as computer products having a central processor or smartphones.

References herein to terms modified by language of approximation, such as “about”, “approximately”, and “substantially”, are not to be limited to the precise value specified. The language of approximation may correspond to the precision of an instrument used to measure the value and, unless otherwise dependent on the precision of the instrument, may indicate +/−10% of the stated value(s).

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction perpendicular to the horizontal, as just defined. The term “lateral” refers to a direction within the horizontal plane.

A feature “connected” or “coupled” to or with another feature may be directly connected or coupled to or with the other feature or, instead, one or more intervening features may be present. A feature may be “directly connected” or “directly coupled” to or with another feature if intervening features are absent. A feature may be “indirectly connected” or “indirectly coupled” to or with another feature if at least one intervening feature is present. A feature “on” or “contacting” another feature may be directly on or in direct contact with the other feature or, instead, one or more intervening features may be present. A feature may be “directly on” or in “direct contact” with another feature if intervening features are absent. A feature may be “indirectly on” or in “indirect contact” with another feature if at least one intervening feature is present. Different features may “overlap” if a feature extends over, and covers a part of, another feature.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
a semiconductor substrate including a trench, the trench surrounding a portion of the semiconductor substrate, and the trench having a sidewall;
a deep trench isolation region including a dielectric layer and a semiconductor layer inside the trench, the dielectric layer between the sidewall of the trench and the semiconductor layer; and
a first active device including a doped region in the semiconductor layer.

2. The structure of claim 1 further comprising:
a single-photon avalanche diode including a terminal in the portion of the semiconductor substrate.

3. The structure of claim 2 further comprising:
a metal feature configured to connect the doped region of the first active device to the terminal of the single-photon avalanche diode.

4. The structure of claim 3 wherein the first active device is a field-effect transistor, and the doped region is a source/drain region of the field-effect transistor.

5. The structure of claim 4 wherein the field-effect transistor includes a gate on the semiconductor layer.

6. The structure of claim 1 wherein the first active device is a field-effect transistor, the doped region is a source/drain region of the field-effect transistor, and the field-effect transistor includes a gate on the semiconductor layer.

7. The structure of claim 1 wherein the semiconductor layer comprises single-crystal silicon.

8. The structure of claim 1 wherein the semiconductor layer comprises amorphous silicon.

9. The structure of claim 1 wherein the semiconductor layer comprises polycrystalline silicon.

10. The structure of claim 1 wherein the dielectric layer of the deep trench isolation region fully surrounds the portion of the semiconductor substrate.

11. The structure of claim 1 wherein the trench includes a bottom, and the semiconductor layer is in direct contact with the semiconductor substrate at the bottom of the trench.

12. The structure of claim 1 wherein the dielectric layer has a thickness in a range of about 0.2 microns to about 0.3 microns.

13. The structure of claim 1 wherein the sidewall of the trench fully surrounds the portion of the semiconductor substrate.

14. The structure of claim 1 wherein the semiconductor substrate has a top surface, the semiconductor layer has a top surface that is coplanar with the top surface of the semiconductor substrate, and the doped region of the first active device is disposed adjacent to the top surface of the semiconductor layer.

15. The structure of claim 14 wherein the doped region of the first active device is coextensive with the top surface of the semiconductor layer.

16. The structure of claim 15 wherein the doped region of the first active device extends from the top surface of the semiconductor layer to a first depth in the semiconductor substrate, and the trench extends from the top surface of the semiconductor substrate to a second depth that is greater than the first depth.

17. The structure of claim 1 wherein the trench has a closed shape.

18. The structure of claim 1 further comprising:
a second active device including a doped region in the semiconductor layer.

19. The structure of claim 18 wherein the first active device is a first field-effect transistor, and the second active device is a second field-effect transistor.

20. A method comprising:
forming a trench in a semiconductor substrate, wherein the trench surrounds a portion of the semiconductor substrate;
forming a deep trench isolation region that includes a dielectric layer and a semiconductor layer inside the trench, wherein the dielectric layer is disposed between a sidewall of the trench and the semiconductor layer; and
forming an active device including a doped region in the semiconductor layer.
